(19) United States
(12) Patent Application Publication
(10) Pub. No.: US 2018/0048836 A1
(43) Pub. Date: Feb. 15, 2018

(54) SOLID-STATE IMAGING DEVICE, DRIVING METHOD, AND ELECTRONIC APPARATUS

(71) Applicant: SONY CORPORATION, Tokyo (JP)

(72) Inventors: Yorito SAKANO, Kanagawa (JP); Hiroki UI, Tokyo (JP)

(21) Appl. No.: 15/556,944

(22) PCT Filed: Mar. 4, 2016
(86) PCT No.: PCT/JP2016/056730

§ 371 Date: Sep. 8, 2017

(30) Foreign Application Priority Data
Mar. 18, 2015 (JP) 2015-054324

(51) Int. Cl. H04N 5/355; H04N 5/378; H01L 27/142; H04N 5/374

(52) U.S. Cl. CPC H04N 5/35563; H04N 5/374; H04N 5/378; H01L 27/142; H04N 9/045

(57) ABSTRACT

The present technology relates to a solid-state imaging device, a driving method, and an electronic apparatus capable of obtaining a high-quality image more easily.

The solid-state imaging device includes a pixel array region in which a plurality of pixels that photoelectrically converts incident light is provided. A first pixel group and a second pixel group having different output characteristics are provided in the pixel array region, and the second pixel group is arranged in a position displaced from the first pixel group in a horizontal direction and in a vertical direction by half a pixel. By arranging the first pixel group and the second pixel group in this manner, deterioration in resolution of an image obtained by photographing may be minimized, and a high-quality image may be obtained more easily. The present technology is applicable to the solid-state imaging device.

### TECHNICAL FIELD

The present technology relates to a solid-state imaging device, a driving method, and an electronic apparatus, and especially relates to the solid-state imaging device, the driving method, and the electronic apparatus capable of obtaining a high-quality image more easily.

### BACKGROUND ART

A logarithmic sensor in a solar cell mode which operates a photodiode in an open circuit as with a solar cell to measure output voltage is conventionally known (refer to Non-Patent Document 1, for example).

In the logarithmic sensor in the solar cell mode, a relationship in which potential difference occurring when current flows in a forward direction of PN junction of the photodiode, that is, voltage is proportional to a logarithm of the current is utilized. That is, by replacing the current in the forward direction of the PN junction in the Shockley equations with photocurrent generated by photoelectric conversion in the PN junction and monitoring the voltage in the forward direction of the PN junction, a monitor result is a signal obtained by logarithmic compression of the photocurrent.

Furthermore, a solid-state imaging device is proposed in which such logarithmic sensor in the solar cell mode and a general accumulation type complementary metal oxide semiconductor (CMOS) image sensor are used in combination as a sensor used for taking an image (for example, refer to Patent Documents 1 and 2).

In this technology, the logarithmic sensor in the solar cell mode and the accumulation type CMOS image sensor are arranged so as to be divided in a space. Then, when taking an image, a pixel signal of each pixel is sequentially read out from a pixel row in which a pixel forming the logarithmic sensor in the solar cell mode and the pixel forming the accumulation type CMOS image sensor are mixed, and the pixel row formed only of the pixels forming the accumulation type CMOS image sensor.

Furthermore, the solid-state imaging device which obtains an image by using the pixel forming the logarithmic sensor in the solar cell mode and the pixel forming the accumulation type CMOS image sensor in a time-division manner is also proposed (refer to, for example, Patent Documents 3 and 4).

According to such solid-state imaging device obtained by combining the logarithmic sensor in the solar cell mode and the accumulation type CMOS image sensor, an image having a wider dynamic range may be obtained.

Meanwhile, the logarithmic sensor in the solar cell mode and the accumulation type CMOS image sensor are combined in the solid-state imaging device because the logarithmic sensor in the solar cell mode has a high illuminance characteristic, but it cannot be said that a low illuminance characteristic of the logarithmic sensor in the solar cell mode is excellent and this is weak in the dark.

When a structure of the logarithmic sensor in the solar cell mode is allowed to correspond to a structure of a general accumulation type CMOS image sensor, this corresponds to a structure obtained by directly providing a contact to a modulation transistor required for modulating the signal obtained by the photoelectric conversion on the photodiode.

Therefore, in the logarithmic sensor in the solar cell mode, since the photodiode cannot be completely depleted, it is not possible to remove kTC noise, an afterimage occurs in the image, and since pinning of a surface of the photodiode cannot be performed, white dots and dark current increase due to an interface state. It is not possible to obtain a sufficient low illuminance characteristic by the logarithmic sensor in the solar cell mode because of them.

On the other hand, the general accumulation type CMOS image sensor provided with a transfer transistor is configured to transfer charge obtained by the photodiode through the transfer transistor to a floating diffusion region being a modulation region. Then, a contact is provided in the floating diffusion region and a voltage signal corresponding to the charge transferred to the floating diffusion region is read out through the modulation transistor to which the contact is connected.

In the general accumulation type CMOS image sensor, deterioration in low illuminance characteristic such as that occurring in the logarithmic sensor in the solar cell mode is suppressed by separating the photodiode from the modulation region.

Therefore, as described above, in the solid-state imaging device using the logarithmic sensor in the solar cell mode, it is proposed to compensate the characteristic of the logarithmic sensor in the solar cell mode that is weak in the dark by combining the same with the accumulation type CMOS image sensor.

### CITATION LIST

### Non-Patent Document

Non-Patent Document 1: Yang Ni, YiMing Zhu, Bogdan Arion “A 768x 576 Logarithmic Image Sensor with Photodiode in Solar Cell mode” 2011 International Image Sensor Workshop (IISW), 2011/6/9, Presentation R 35

### Patent Document

Patent Document 1: Japanese Patent Application Laid-Open No. 2013-187727

Patent Document 2: Japanese Patent Application Laid-Open No. 2013-187728

Patent Document 3: Japanese Patent Application Laid-Open No. 2013-58960

Patent Document 4: Japanese Patent Application Laid-Open No. 2013-118595

### SUMMARY OF THE INVENTION

### Problems to be Solved by the Invention

However, in the above-described technology, it is not possible to easily obtain a high-quality image in a solid-state imaging device obtained by combining a logarithmic sensor in a solar cell mode and an accumulation type CMOS image sensor.

For example, when pixels forming the logarithmic sensor in the solar cell mode and pixels forming the accumulation type CMOS image sensor are simply arranged as disclosed in Patent Document 1, for the sensors, a sampling cycle in a space increases in a vertical direction and a horizontal direction and resolution of the image is deteriorated. Furthermore, in this case, the sampling cycle in the sensor is not uniform between the horizontal direction and the vertical direction.

Furthermore, not only the order of reading out a signal level and a reset level differs between the pixels forming the logarithmic sensor in the solar cell mode and the pixels forming the accumulation type CMOS image sensor, but also the levels of the signal level and the reset level are also different. Furthermore, depending on a pixel configuration, a direction in which the signal level changes might be different.

Therefore, if the signals are read out from the pixels forming the logarithmic sensor in the solar cell mode and the pixels forming the accumulation type CMOS image sensor by using the same vertical signal line, not only a readout circuit becomes complicated but also a reading speed is limited.

The present technology is achieved in view of such a condition, and an object thereof is to more easily obtain a high-quality image.

### Solutions to Problems

A solid-state imaging device according to a first aspect of the present technology is provided with a first pixel group formed of a plurality of first pixels arranged in a matrix, and a second pixel group formed of a plurality of second pixels having a characteristic different from a characteristic of the first pixels arranged in a matrix such that each of the second pixel is displaced by half a pixel in a row direction and in a column direction from each of the first pixels forming the first pixel group.

The first pixel and the second pixel may be pixels having different output characteristics with respect to an amount of incident light.

The first pixel may be a pixel having a linear characteristic as the characteristic.

The second pixel may be a pixel having a log characteristic as the characteristic.

The first pixel may be a pixel forming an accumulation type CMOS image sensor and the second pixel may be a pixel forming a logarithmic sensor in a solar cell mode.

A pixel row formed of the first pixels arranged in the row direction and a pixel row formed of the second pixels arranged in the row direction adjacent to the pixel row in the column direction may be simultaneously selected and driven.

The solid-state imaging device may be further provided with a first vertical signal line for reading out signals from the first pixels to which only the first pixels arranged in the column direction are connected, and a second vertical signal line for reading out signals from the second pixels to which only the second pixels arranged in the column direction are connected.

The solid-state imaging device may be a solid-state imaging device that takes a color image.

A driving method of according to the first aspect of the present technology is a driving method of a solid-state imaging device provided with a first pixel group formed of a plurality of first pixels arranged in a matrix, and a second pixel group formed of a plurality of second pixels having a characteristic different from a characteristic of the first pixels arranged in a matrix such that each of the second pixel is displaced by half a pixel in a row direction and in a column direction from each of the first pixels forming the first pixel group, the driving method provided with steps of reading out signals from the first pixels, and reading out signals from the second pixels.

According to the first aspect of the present technology, a solid-state imaging device is provided with a first pixel group formed of a plurality of first pixels arranged in a matrix, and a second pixel group formed of a plurality of second pixels having a characteristic different from a characteristic of the first pixels arranged in a matrix such that each of the second pixel is displaced by half a pixel in a row direction and in a column direction from each of the first pixels forming the first pixel group.

An electronic apparatus according to a second aspect of the present technology is provided with a solid-state imaging device provided with a first pixel group formed of a plurality of first pixels arranged in a matrix, and a second pixel group formed of a plurality of second pixels having a characteristic different from a characteristic of the first pixels arranged in a matrix such that each of the second pixel is displaced by half a pixel in a row direction and in a column direction from each of the first pixels forming the first pixel group.

According to the second aspect of the present technology, a solid-state imaging device is provided with a first pixel group formed of a plurality of first pixels arranged in a matrix, and a second pixel group formed of a plurality of second pixels having a characteristic different from a characteristic of the first pixels arranged in a matrix such that each of the second pixel is displaced by half a pixel in a row direction and in a column direction from each of the first pixels forming the first pixel group.

### Effects of the Invention

According to the first and second aspects of the present technology, a high-quality image may be obtained more easily.

### BRIEF DESCRIPTION OF DRAWINGS

FIG. 1 is a view illustrating a pixel array.

FIG. 2 is a view illustrating readout of a signal level and a reset level.

FIG. 3 is a view illustrating the pixel array to which the present technology is applied.

FIG. 4 is a view illustrating pixel wiring.

FIG. 5 is a view illustrating a configuration example of a solid-state imaging device.

FIG. 6 is a view illustrating a configuration example of a linear pixel.

FIG. 7 is a view illustrating a configuration example of a log pixel.

FIG. 8 is a view for illustrating driving of the linear pixel.

FIG. 9 is a view illustrating driving of the log pixel.

FIG. 10 is a view illustrating a configuration example of an imaging device.

FIG. 11 is a view illustrating a usage example of the solid-state imaging device is used.

### MODE FOR CARRYING OUT THE INVENTION

Embodiments to which the present technology is applied are hereinafter described with reference to the drawings.

### First Embodiment

### Regarding Pixel Array of Solid-State Imaging Device

According to the present technology, in a case where pixels having different characteristics are arranged in a space, the pixels having different characteristics are arranged in a two-dimensional manner in a matrix so as to be displaced by half a pixel in a row direction (horizontal direction) and in a column direction (vertical direction) such that a high-quality image may be obtained more easily.

Herein, although the pixels having different characteristics are not limited, in the following description, it is assumed that the pixels are the pixels a characteristic of an output with respect to an amount of received incident light (output characteristic) of which is a linear characteristic and a log characteristic (logarithmic characteristic).

Specifically, the pixel having the linear characteristic as the output characteristic is the pixel (hereinafter also referred to as a linear pixel) formed of an embedded photodiode which forms, for example, an accumulation type CMOS image sensor. The linear pixel outputs a voltage signal proportional to the amount of received incident light.

Furthermore, the pixel having the log characteristic as the output characteristic is the pixel (hereinafter also referred to as a log pixel) formed of a surface type photodiode which forms, for example, a logarithmic sensor in a solar cell mode. The log pixel outputs a voltage signal proportional to a logarithmic value of the amount of received incident light.

Hereinafter, as a specific embodiment, a solid-state imaging device including a pixel array region in which the accumulation type CMOS image sensor formed of the linear pixel and the logarithmic sensor in the solar cell mode formed of the log pixel are arranged so as to be divided in the space is described.

Meanwhile, the pixel array in the pixel array region of the solid-state imaging device may be a color array for taking a color image or a monochrome array for taking a monochrome image; the pixel array of the pixel array region is hereinafter the color array.

In such a case, for example, pixels including color filters of respective colors of R (red), G (green), and B (blue) are arranged as the linear pixels in the pixel array region.

Hereinafter, a linear pixel including the R color filter which outputs an R component signal is also referred to as an R_{LNR} pixel, and a linear pixel including the G color filter which outputs a G component signal is also referred to as a G_{LNR} pixel. Furthermore, a linear pixel including the B color filter which outputs a B component signal is also referred to as a B_{LNR} pixel.

Similarly, in the pixel array region, the pixels including the color filters of respective colors of R, G, and B are arranged as the log pixels.

Hereinafter, a log pixel including the R color filter which outputs the R component signal is also referred to as an R_{LOG} pixel, a log pixel including the G color filter which outputs the G component signal is also referred to as a G_{LOG} pixel. Furthermore, a log pixel including the B color filter which outputs the B component signal is also referred to as a B_{LOG} pixel.

In the pixel array region of the solid-state imaging device to which the present technology is applied, the linear pixels of respective colors are arranged in a Bayer array, and the log pixels of respective colors are also arranged in the Bayer array.

The solid-state imaging device obtains one image from an image obtained by photographing a subject with the linear pixel, that is, the accumulation type CMOS image sensor (hereinafter, also referred to as a linear image) and an image obtained by photographing the subject with the log pixel, that is, the logarithmic sensor in the solar cell mode (hereinafter, also referred to as a log image). In this manner, it is possible to obtain a high-quality image with a wide dynamic range by combining the linear pixel with an excellent low-luminance characteristic and the log pixel with an excellent high-luminance characteristic to obtain one final image.

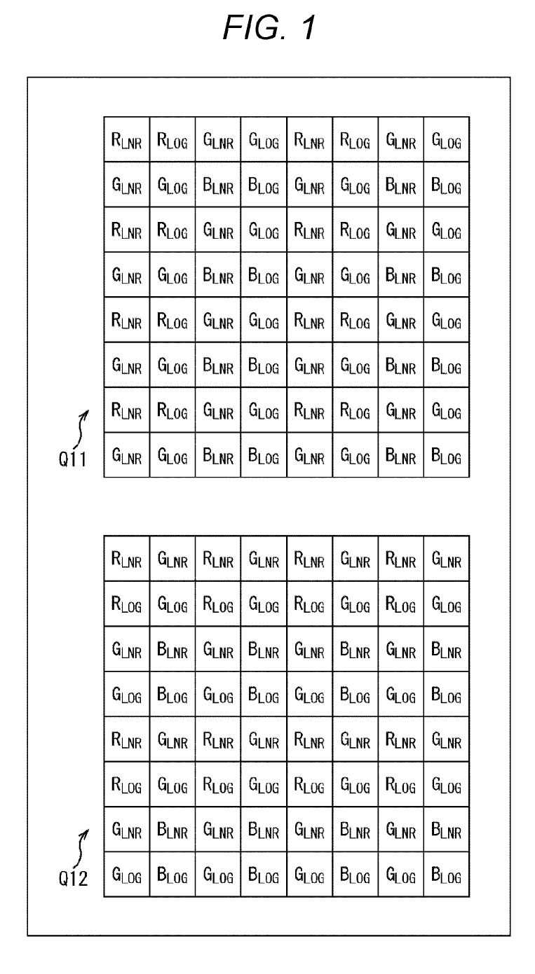

Herein, in a case where the linear pixels and the log pixels are arranged in the Bayer array in the pixel array region, for example, there may be a case where the linear pixels and the log pixels are simply arranged alternately in a longitudinal direction or in a lateral direction as illustrated in FIG. 1. Meanwhile, in FIG. 1, it is assumed that the lateral direction in the drawing is the horizontal direction in the pixel array region, that is, the row direction, and the longitudinal direction in the drawing is the vertical direction in the pixel array region, that is, the column direction.

Furthermore, in FIG. 1, each square represents one pixel, and characters “R_{LNR}”, “G_{LNR}”, “B_{LNR}”, “R_{LOG}”, “G_{LOG}”, and “B_{LOG}” in the pixels indicate that the pixels are the R_{LNR} pixel, the G_{LNR} pixel, the B_{LNR} pixel, the R_{LOG} pixel, the G_{LOG} pixel, and the B_{LOG} pixel, respectively.

In FIG. 1, in an example indicated by arrow Q11, a linear pixel column in which the linear pixels are arranged in the column direction and a log pixel column in which the log pixels are arranged in the column direction are alternately arranged in the row direction. Furthermore, focusing only on the linear pixels, the linear pixels of respective colors are arranged in the Bayer array, and similarly, focusing only on the log pixels, the log pixels of respective colors are arranged in the Bayer array.

On the other hand, in an example indicated by arrow Q12, a linear pixel row in which the linear pixels are arranged in the row direction and a log pixel row in which the log pixels are arranged in the row direction are alternately arranged in the column direction. Furthermore, focusing only on the linear pixels, the linear pixels of respective colors are arranged in the Bayer array, and similarly, focusing only on the log pixels, the log pixels of respective colors are arranged in the Bayer array.

In a case where the linear pixels and the log pixels are arranged in the pixel array indicated by arrows Q11 and Q12, a sampling cycle in the space of the linear image and the log image is doubled in any of the row direction (horizontal direction) and the column direction (vertical direction) as compared to a case where only the linear pixels or the log pixels are arranged.

For example, the sampling cycle in the space of the linear image obtained in a case where only the linear pixels are arranged in the pixel array region (hereinafter also referred to as a reference linear image) , that is, a distance between centers of adjacent linear pixels corresponds to one-pixel pitch (width of one pixel) in both the horizontal direction and vertical direction.

On the other hand, in the pixel array indicated by arrow Q11, although the sampling cycle in the vertical direction of the linear image is one-pixel pitch, the log pixel is arranged between the linear pixels in the horizontal direction, so that the sampling cycle in the horizontal direction of the linear image corresponds to two-pixel pitch.

Therefore, in the pixel array indicated by arrow Q11, the sampling cycle in the horizontal direction of the linear image is twice the sampling cycle of the reference linear image. In other words, a sampling frequency in the horizontal direction of the linear image is deteriorated by half.

Then, resolution in the horizontal direction of the linear image obtained by photographing is deteriorated by half as compared to that of the reference linear image. Such deterioration in resolution might cause false color and the like.

Furthermore, in this case, the sampling cycles in the horizontal direction and the vertical direction of the linear image are different. That is, the resolution in the horizontal direction and the vertical direction of the linear image are not uniform.

Such deterioration in resolution and non-uniform resolution between directions occur not only in the linear image but also in the log image.

Similarly, in the pixel array indicated by arrow Q12, the resolution in the vertical direction of the linear image and the log image is deteriorated by half, and the resolution is not uniform between the horizontal direction and the vertical direction.

Furthermore, in a case where the linear pixels and the log pixels are arranged in a mixed manner in the pixel array region as indicated by arrows Q11 and Q12, inconvenience occurs also in pixel wiring and signal readout.

For example, in the pixel array indicated by arrow Q11, it is necessary to arrange horizontal signal lines of both the linear pixels and the log pixels side by side in the longitudinal direction in the drawing at one-pixel pitch, so that in a case where the solid-state imaging device is a surface irradiation image sensor, an aperture ratio of the pixel is deteriorated.

Furthermore, since the order of signal readout and levels of the signals themselves are different between the linear pixel and the log pixel, if the signals are to be read out through the same vertical signal line from the linear pixels and the log pixels in the pixel array indicated by arrow Q12, a readout circuit becomes complicated. Furthermore, a readout speed of the signal from the pixel is also limited.

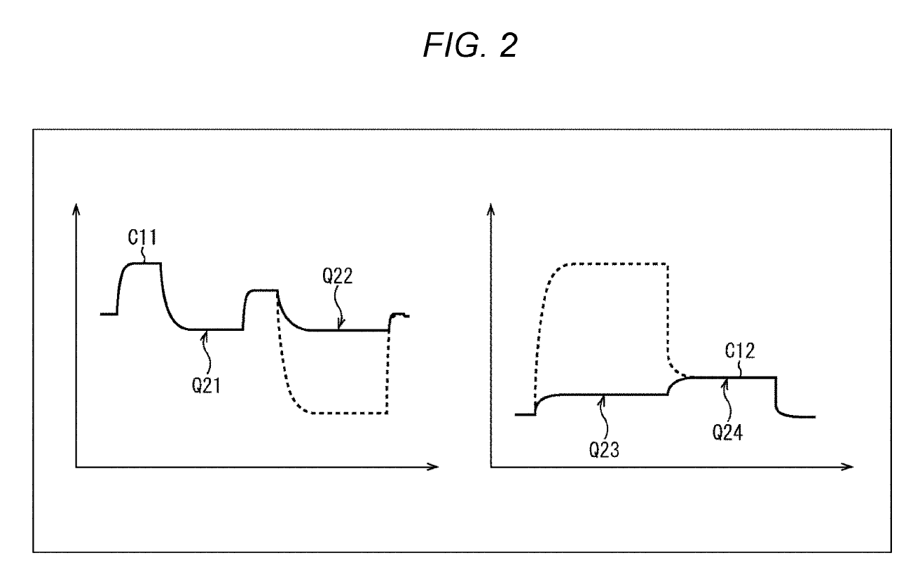

For example, an output signal waveform when reading out the signal from the linear pixel and the output signal waveform when reading out the signal from the log pixel are as illustrated in FIG. 2. Meanwhile, in FIG. 2, voltage output from the pixel, that is, the level of the signal is plotted along the ordinate axis, and time is plotted along the abscissa axis in the drawing.

In FIG. 2, curve C11 indicates the output signal waveform when the signal is read out from the linear pixel, and curve C12 indicates the output signal waveform when the signal is read out from the log pixel.

In a case where the signal is read out from the linear pixel, the pixel is first reset, then a reset level is read out, and further the signal level is read out after the signal is transferred to a floating diffusion region.

In this example, a portion indicated by arrow Q21 indicates the reset level of the linear pixel, and a portion indicated by arrow Q22 indicates the signal level.

On the other hand, in a case where the signal is read out from the log pixel, the signal level is first read out and then the reset level is read out. In this example, a portion indicated by arrow Q23 indicates the signal level of the log pixel, and a portion indicated by arrow Q24 indicates the reset level.

In this manner, the readout order of the signal level and the reset level and the levels of the signals are different between the linear pixel and the log pixel. Furthermore, depending on a pixel configuration, carriers of photoelectric conversion elements forming the pixels might be different between the linear pixel and the log pixel, and in such a case, a direction in which the signal level changes also differs. In this example, the direction in which the signal level changes is different between the portion indicated by arrow Q22 and the portion indicated by arrow Q23 as indicated by dotted lines.

Therefore, in a case where the linear pixel and the log pixel are connected to the same vertical signal line, if the signals are to be read out from the linear pixel and the log pixel by using the vertical signal line, not only a configuration of the readout circuit becomes complicated but also the readout speed is also limited.

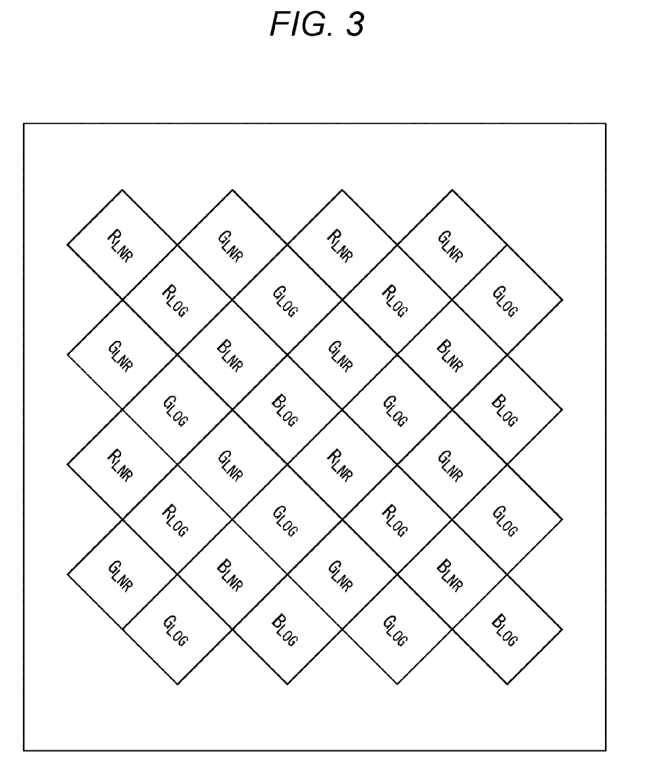

Therefore, in the solid-state imaging device to which the present technology is applied, for example, as illustrated in FIG. 3, a log pixel group is arranged in a position displaced at a half-pixel pitch (half-pixel width) in the row direction and the column direction from a linear pixel group in the pixel array region.

Meanwhile, in FIG. 3, a lateral direction in the drawing indicates the horizontal direction (row direction) in the pixel array region, and a longitudinal direction in the drawing indicates the vertical direction (column direction) in the pixel array region. Furthermore, in FIG. 3, each square represents one pixel, and characters “R_{LNR}”, “G_{LNR}”, “B_{LNR}”, “R_{LOG}”, “G_{LOG}”, and B_{LOG} in the pixels indicate that the pixels are the R_{LNR} pixel, the G_{LNR} pixel, the B_{LNR} pixel, the R_{LOG} pixel, the G_{LOG} pixel, and the B_{LOG} pixel, respectively.

In FIG. 3, focusing only on the linear pixels, the linear pixels of respective colors are arranged in a two-dimensional manner in the row direction and the column direction, that is, in a matrix in the Bayer array. Similarly, focusing only on the log pixels, the log pixels of respective colors are arranged in a two-dimensional manner in a matrix in the Bayer array.

In this example, the log pixel group is arranged in a matrix in a position displaced at a half-pixel pitch in the row direction and the column direction with respect to the linear pixel group arranged in a matrix.

In other words, other linear pixels are arranged adjacently on upper, lower, right and left sides of each linear pixel, and the log pixels are arranged adjacently in oblique directions of each linear pixel at an angle of 45 degrees, that is, diagonally upward right, diagonally downward right, diagonally upward left, and diagonally downward left. Herein, the oblique direction at an angle of 45 degrees is a direction at an angle of 45 degrees with respect to the horizontal direction (row direction) or the vertical direction (column direction).

Also, as seen from each linear pixel, only the linear pixels are arranged in the row direction and the column direction with respect to the linear pixel. Similarly, as seen from each log pixel, only the log pixels are arranged in the row direction and the column direction with respect to the log pixel.

By making such a pixel array, in the solid-state imaging device to which the present technology is applied, it is possible to minimize deterioration in resolution of the linear image and the log image and to obtain the image of uniform resolution in the horizontal direction and the vertical direction.

That is, in this example, the pixels are arranged in a two-dimensional manner in a state in which each pixel is rotated by 45 degrees with respect to the example illustrated in FIG. 1, that is, in a state where the sides of the square representing the pixel form an angle of 45 degrees with respect to the horizontal direction.

Therefore, the sampling cycle in the row direction and the column direction of the linear image corresponds to 2^{1/2}- pixel pitch. In other words, the sampling frequency of the linear image is 1/(2^{1/2}) times the sampling frequency of the reference linear image. Furthermore, the sampling cycle of the linear image is the same in the row direction and the column direction.

Therefore, the deterioration in resolution of the linear image is less than that in the case of the pixel array illustrated in FIG. 1, and in addition, the resolution of the linear image is uniform in the horizontal direction and the vertical direction. Furthermore, the deterioration in resolution may be minimized not only in the linear image but also in the log image, and it is possible to make the resolution in the horizontal and vertical directions uniform.

In addition, in the pixel array illustrated in FIG. 3, the linear pixel and the log pixel of the same color are arranged in positions displaced at a half-pixel pitch in the horizontal direction and the vertical direction, and spatial displacement in sampling position between the linear pixel and the log pixel is also minimized.

From above, by making the pixel array in the pixel array region the array as illustrated in FIG. 3, it is possible to obtain a higher-quality image more easily. That is, it is possible to realize a higher quality color image obtained by the solid-state imaging device more easily.

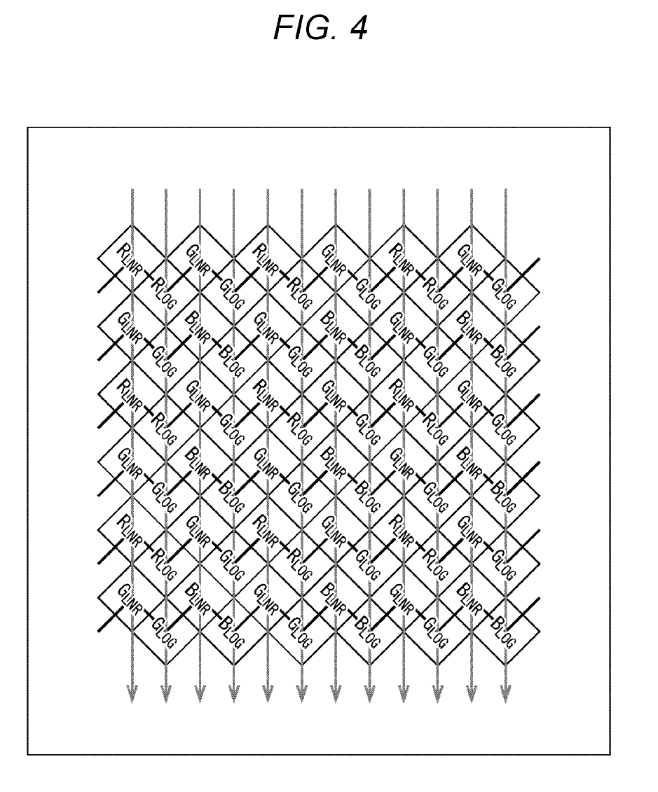

Furthermore, by making the pixel array the pixel array as illustrated in FIG. 3, wiring may be performed as illustrated in FIG. 4. Meanwhile, FIG. 4 is obtained by further drawing the wiring in the pixel array in FIG. 3, and description of the portion corresponding to that in FIG. 3 is omitted in FIG. 4. Furthermore, in FIG. 4, a longitudinal direction and a lateral direction indicate the vertical direction (column direction) and the horizontal direction (row direction) in the pixel array region.

In FIG. 4, a polygonal line extending in the horizontal direction connecting the pixels represents a signal line (horizontal signal line) for driving the pixels, and a vertical straight line connecting the pixels arranged in the vertical direction represents a vertical signal line used for reading out the signal from the pixel.

By making the pixel array the pixel array described with reference to FIG. 3, it is only necessary to provide the horizontal signal lines of both the linear pixels and the log pixels at a 2^{1/2}-pixel pitch as illustrated in FIG. 4, so that it is possible to suppress the deterioration in aperture ratio of the pixel.

Furthermore, in the pixel array described with reference to FIG. 3, only the linear pixels or only the log pixels are arranged in the vertical direction. Therefore, as illustrated in FIG. 4, the pixels connected to one vertical signal line are necessarily only the linear pixels or only the log pixels.

Then, at the time of readout of the signal from the pixel, it is possible to separate the readout of the signals from the linear pixels and the readout of the signals from the log pixels.

Therefore, for example, the readout circuit for linear pixel is connected to the vertical signal line connected to the linear pixels, and the readout circuit for log pixel is connected to the vertical signal line connected to the log pixels, and the readout circuit maybe prevented from becoming complicated. That is, signals may be readout from the pixels with a simpler circuit configuration.

Moreover, by independently operating the readout circuit for linear pixel and the readout circuit for log pixel, it is possible to avoid interference of circuit operation of both the circuits and operate the readout circuit at a higher speed. As a result, it becomes possible to obtain a higher-quality image more simply and more quickly.

Meanwhile, a timing to read out the signal from the linear pixel and a timing to read out the signal from the log pixel may be the same timing or different timings as long as the readout timings are within a period of one frame of the image to be taken. Furthermore, exposure time and an exposure timing of the linear pixel and the log pixel may also be the same or different.

### Configuration Example of Solid-State Imaging Device

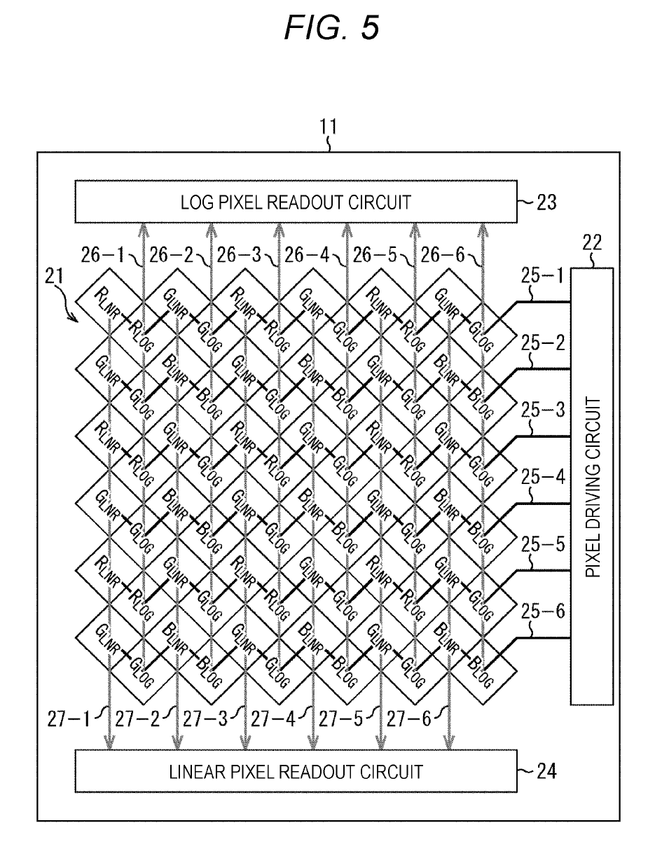

Subsequently, a more specific embodiment of the solid-state imaging device described above is described. FIG. 5 is a view illustrating a configuration example of one embodiment of the solid-state imaging device to which the present technology is applied.

Meanwhile, in FIG. 5, each square represents one pixel, and the characters “R_{LNR}”, “G_{LNR}”, “B_{LNR}”, “R_{LOG}”, “G_{LOG} ”, and “B_{LOG”} in the pixels indicate that the pixels are the R_{LNR} pixel, the G_{LNR} pixel, the B_{LNR} pixel, the R_{LOG} pixel, the G_{LOG} pixel, and the B_{LOG} pixel, respectively. Furthermore, in the drawing, a lateral direction indicates the horizontal direction (row direction) in a pixel array region 21, and a longitudinal direction in the drawing indicates the vertical direction (column direction) in the pixel array region 21.

A solid-state imaging device 11 illustrated in FIG. 5 is the solid-state imaging device that takes a color image, and the solid-state imaging device 11 includes the pixel array region 21, a pixel driving circuit 22, a log pixel readout circuit 23, and a linear pixel readout circuit 24.

In the pixel array region 21, the linear pixels and the log pixels are arranged in a two-dimensional manner in a matrix in the pixel array illustrated in FIG. 3, and each pixel photoelectrically converts light incident from the subject and outputs a signal corresponding to a result.

Furthermore, each pixel in the pixel array region 21 is connected to the pixel driving circuit 22 through any of driving signal lines 25-1 to 25-6. Meanwhile, hereinafter, in a case where the driving signal lines 25-1 to 25-6 are not necessarily required to be distinguished from each other, they are also simply referred to as driving signal lines 25.

The pixel in the pixel array region 21 is connected to the driving signal line 25 as described with reference to FIG. 4. That is, in the pixel array region 21, a pixel row formed of the linear pixels arranged in the row direction (horizontal direction) and a pixel row formed of the log pixels arranged in the row direction below the above-described pixel row in the drawing so as to be adjacent thereto are connected to one (same) driving signal line 25. In this example, each driving signal line 25 is wired in a zigzag manner so as to be alternately connected to the linear pixel and the rig pixel.

Furthermore, each pixel column formed of the log pixels arranged in the vertical direction in the pixel array region 21 is connected to the log pixel readout circuit 23 through any of vertical signal lines 26-1 to 26-6 elongated in the vertical direction. Meanwhile, hereinafter, the vertical signal lines 26-1 to 26-6 are also simply referred to as the vertical signal lines 26 in a case where it is not especially necessary to distinguish them from each other.

In this example, each log pixel arranged in the vertical direction forming the pixel column is connected to one vertical signal line 26. In other words, only the log pixels are connected to the vertical signal line 26.

Similarly, each pixel column formed of the linear pixels arranged in the vertical direction in the pixel array region 21 is connected to the linear pixel readout circuit 24 through any of vertical signal lines 27-1 to 27-6 elongated in the vertical direction. Meanwhile, hereinafter, when the vertical signal lines 27-1 to 27-6 are also simply referred to as vertical signal lines 27 in a case where it is not especially necessary to distinguish them.

In this example, each linear pixel arranged in the vertical direction forming the pixel column is connected to one vertical signal line 27. In other words, only the linear pixels are connected to the vertical signal line 27.

The pixel driving circuit 22 drives each pixel by supplying a driving signal to each pixel through the driving signal line 25.

For example, the pixel driving circuit 22 selects several pixel rows arranged in succession in the vertical direction as shutter lines being pixel rows which perform shutter operation, that is, starts exposure. Then, the pixel driving circuit 22 supplies various driving signals to each pixel forming the shutter lines through the driving signal line 25 to cause the shutter operation.

Furthermore, the pixel driving circuit 22 selects several pixel rows arranged in succession in the vertical direction at a position separated from the shutter lines by a predetermined number of rows as read lines which read out signals from the pixels. Then, the pixel driving circuit 22 supplies various driving signals to each pixel forming the read lines through the driving signal line 25 to output the signal.

The pixel driving circuit 22 scans the shutter lines and the read lines in the vertical direction such that they move in the vertical direction over time. At that time, for example, the pixel driving circuit 22 simultaneously selects or simultaneously drives each linear pixel of the pixel row formed of the linear pixels and each log pixel of the pixel row formed of the log pixels adjacent to the above-described pixel row.

Meanwhile, although the pixel driving circuit 22 is herein connected to each pixel by one driving signal line 25, more specifically, the pixel driving circuit 22 is connected to each pixel by a plurality of driving signal lines 25. For example, the driving signal line 25 is provided for each type of driving signal to be supplied to the pixel.

The log pixel readout circuit 23 reads out the signal level and the reset level from the log pixel through the vertical signal line 26 and calculates a pixel signal indicating a pixel value of the corresponding log pixel on the log image from the signal level and the reset level to output to a block at a subsequent stage.

The linear pixel readout circuit 24 reads out the signal level and the reset level from the linear pixel through the vertical signal line 27 and calculates a pixel signal indicating a pixel value of the corresponding linear pixel on the linear image from the signal level and the reset level to output to the block at the subsequent stage.

From a color log image formed of the pixel signals of the log pixels and a color linear image formed of the pixel signals of the linear pixels obtained in this manner, one color image is generated by signal processing to be the final image photographed by the solid-state imaging device 11. Meanwhile, the processing of generating the final image is performed by the block at the subsequent stage of the log pixel readout circuit 23 and the linear pixel readout circuit 24; the block may be provided in the solid-state imaging device 11 or may be provided outside the solid-state imaging device 11.

In the solid-state imaging device 11, as illustrated in FIG. 5, peripheral circuits such as the log pixel readout circuit 23 and the linear pixel readout circuit 24 are arranged around the pixel array region 21, so that it is possible to make use of a characteristic of the pixel array described with reference to FIG. 3.

### Regarding Configuration of Linear Pixel

Herein, a specific configuration example of the linear pixel and the log pixel provided in the pixel array region 21 is described.

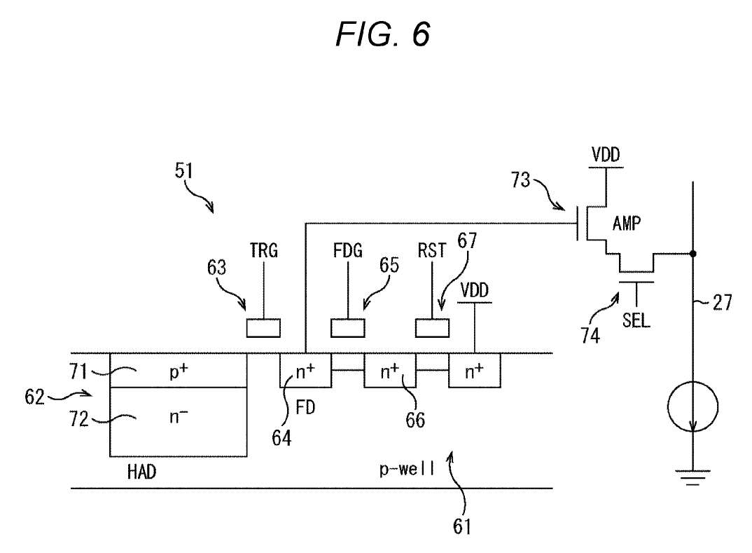

The linear pixel provided in the pixel array region 21 is configured as illustrated in FIG. 6, for example. Meanwhile, in FIG. 6, the same reference sign is assigned to a portion corresponding to that in FIG. 5 and the description thereof is appropriately omitted.

In a linear pixel 51 illustrated in FIG. 6, a photodiode 62 being a photoelectric conversion element, a transfer transistor 63, a charge-voltage converter 64, a transistor 65, a capacitance 66, and a reset transistor 67 are provided in a p-type well 61 on a semiconductor substrate.

The photodiode 62 being am embedded photodiode formed of a p+-type semiconductor region 71 and an n−-type semiconductor region 72 provided in the p-type well 61 photoelectrically converts the incident light and accumulates a charge obtained as a result. Furthermore, the transfer transistor 63 provided between the photodiode 62 and the charge-voltage converter 64 is put into a conduction state (turned on) when a driving signal TRG supplied to a gate electrode thereof reaches a high level and transfers the charge accumulated in the photodiode 62 to the charge-voltage converter 64.

The charge-voltage converter 64 being a floating diffusion region formed of an n+-type semiconductor region provided in the p-type well 61 accumulates the charge supplied from the photodiode 62 through the transfer transistor 63 and converts the accumulated charge to a voltage signal. Furthermore, a gate electrode of an amplification transistor 73 is connected to the charge-voltage converter 64.

The amplification transistor 73 a drain of which is connected to a power source of predetermined voltage VDD serves as an input unit of a source follower circuit that reads the charge (voltage signal) accumulated in the charge-voltage converter 64. That is, the amplification transistor 73 a source of which is connected to the vertical signal line 27 through a selection transistor 74 forms the source follower circuit together with a constant current source connected to one end of the vertical signal line 27.

The selection transistor 74 is connected between the source of the amplification transistor 73 and the vertical signal line 27. The selection transistor 74 is turned on, that is, put into the conduction state when a driving signal SEL supplied to a gate electrode thereof reaches a high level, and supplies the voltage signal output from the amplification transistor 73 to the linear pixel readout circuit 24 through the vertical signal line 27.

The transistor 65 is formed of a p−-type semiconductor region or an n−-type semiconductor region and a gate electrode provided between the charge-voltage converter 64 and the capacitance 66 in the p-type well 61. The transistor 65 is put into a conduction state (turned on) when a driving signal FDG supplied to the gate electrode reaches a high level, and electrically connects the charge-voltage converter 64 to the capacitance 66.

The capacitance 66 formed of an n+-type semiconductor region accumulates a part of the charges transferred to the charge-voltage converter 64 when being electrically connected to the charge-voltage converter 64. Furthermore, the capacitance 66 is initialized (reset) when a driving signal RST supplied to a gate electrode of a reset transistor 67 reaches a high level and the reset transistor 67 is turned on.

### Regarding Configuration of Log Pixel

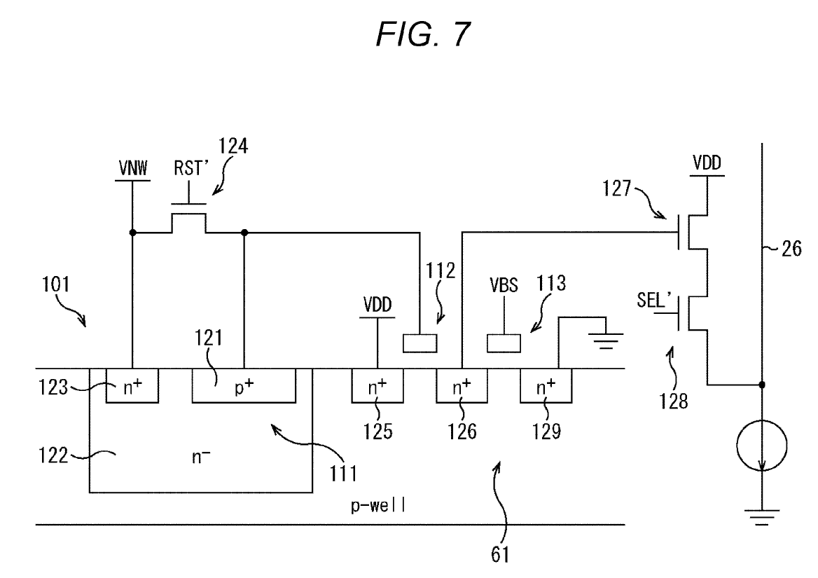

Furthermore, the log pixel provided in the pixel array region 21 is configured as illustrated in FIG. 7, for example. Meanwhile, in FIG. 7, the same reference sign is assigned to a portion corresponding to that in FIG. 5 or 6 and the description thereof is appropriately omitted.

In a log pixel 101 illustrated in FIG. 7, a photodiode 111 being a photoelectric conversion element, a modulation transistor 112, and a transistor 113 for constant current are provided in the p-type well 61 on the semiconductor substrate.

The photodiode 111 is a surface type photodiode formed of a p+-type semiconductor region 121 and an n−-type semiconductor region 122 provided in the p-type well 61.

Furthermore, an n+-type semiconductor region 123 is formed in the n−-type semiconductor region 122, and a reset transistor 124 is provided between the n+-type semiconductor region 123 and the p+-type semiconductor region 121. When a driving signal RST′ supplied to a gate electrode of the reset transistor 124 reaches a high level and the reset transistor 124 is turned on, potential of the p+-type semiconductor region 121 is equal to that of the n−-type semiconductor region 122 and the photodiode 111 is initialized (reset).

The modulation transistor 112 is formed of an n+-type semiconductor region 125 and an n+-type semiconductor region 126 provided in the p-type well 61 and a gate electrode, and the gate electrode of the modulation transistor 112 is connected to the p+-type semiconductor region 121 forming the photodiode 111.

Furthermore, in the log pixel 101, an amplification transistor 127 and a selection transistor 128 corresponding to the amplification transistor 73 and the selection transistor 74 forming the linear pixel 51 illustrated in FIG. 6 are provided.

The amplification transistor 127 a drain of which is connected to a power source of predetermined voltage VDD serves as an input unit of a source follower circuit which reads out a voltage signal obtained by receiving the incident light by the photodiode 111 and further modulated (amplified) by the modulation transistor 112. That is, the amplification transistor 127 a source of which is connected to the vertical signal line 26 through the selection transistor 128 forms the source follower circuit together with a constant current source connected to one end of the vertical signal line 26. Furthermore, a gate electrode of the amplification transistor 127 is connected to the n+-type semiconductor region 126 forming the modulation transistor 112.

The selection transistor 128 is connected between the source of the amplification transistor 127 and the vertical signal line 26. When a driving signal SEL′ supplied to a gate electrode reaches a high level, the selection transistor 128 is turned on, that is, put into a conduction state, and supplies a voltage signal output from the amplification transistor 127 to the log pixel readout circuit 23 through the vertical signal line 26.

The transistor 113 for constant current is formed of an n+-type semiconductor region 126 and an n+-type semiconductor region 129 provided in the p-type well 61 and a gate electrode, and bias voltage VBS is applied to the gate electrode of the transistor 113.

When light is externally incident on the photodiode 111, holes move from the p+-type semiconductor region 121 to the n−-type semiconductor region 122 in accordance with the amount of incident light (received light amount), and voltage to be applied to the gate electrode of the modulation transistor 112 changes accordingly.

The voltage applied to the gate electrode of the modulation transistor 112, that is, the voltage signal obtained by the photodiode 111 is amplified by the modulation transistor 112 and the transistor 113, and further output to the vertical signal line 26 through the amplification transistor 127 and the selection transistor 128.

In a case where the linear pixel 51 and the log pixel 101 described above are provided in the pixel array region 21, for example, the driving signal line 25 for supplying the driving signal SEL and the driving signal SEL′ may be the same driving signal line.

### Regarding Operation of Solid-State Imaging Device

Subsequently, operation of the solid-state imaging device 11 is described.

The solid-state imaging device 11 starts photographing processing when being instructed to photograph the subject, and outputs the linear image and the log image.

That is, the pixel driving circuit 22 selects the shutter line and the read line, and supplies various driving signals to each pixel in the pixel array region 21 through the driving signal lines 25 according to a selection result. At that time, the pixel driving circuit 22 drives each pixel while scanning the shutter line and the read line in the vertical direction over time.

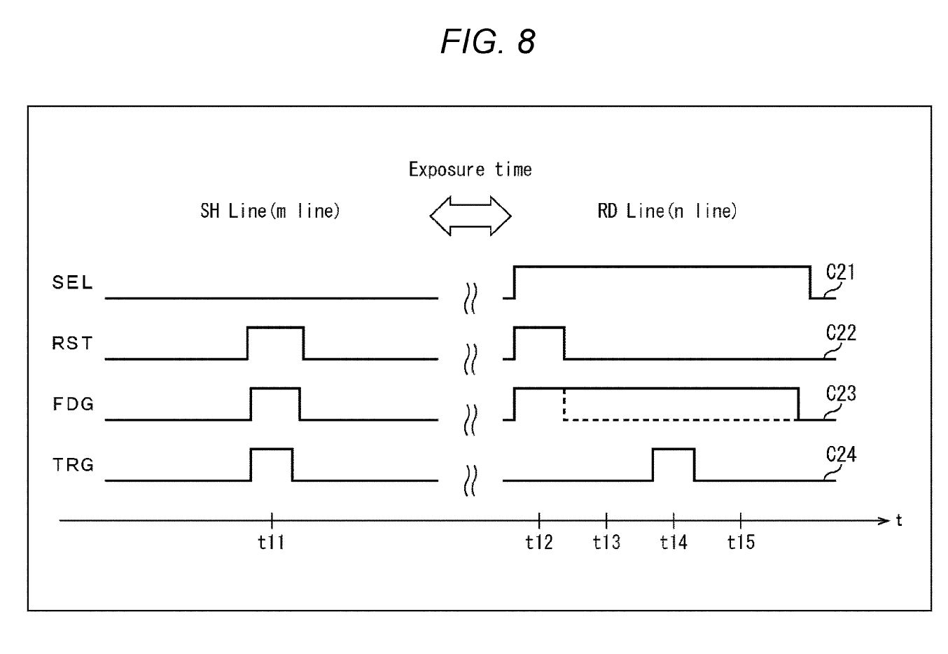

Specifically, the linear pixel 51 provided in the pixel array region 21 is driven, for example, as illustrated in FIG. 8.

Meanwhile, in FIG. 8, polygonal lines C21 to C24 indicate driving waveforms of the driving signal SEL, the driving signal RST, the driving signal FDG, and the driving signal TRG described above, respectively. Furthermore, in FIG. 8, time is plotted in a lateral direction, and the level of each driving signal is plotted in a longitudinal direction. That is, a state in which the driving signal projects upward indicates a high level state, and a state in which the driving signal projects downward indicates a low level state.

In this example, in a case where the pixel row including the linear pixel 51 is not selected as either a shutter line or a read line, the driving signal SEL, the driving signal RST, the driving signal FDG, and the driving signal TRG are set to the low levels.

That is, the selection transistor 74, the reset transistor 67, the transistor 65, and the transfer transistor 63 are turned off.

In such a state, when the pixel row including the linear pixel 51 is selected as the shutter line, the pixel driving circuit 22 puts the driving signal RST, the driving signal FDG, and the driving signal TRG supplied to the linear pixel 51 through the driving signal line 25 to the high levels at time t11.

As a result, the transfer transistor 63 and the transistor 65 are turned on, and the photodiode 62, the charge-voltage converter 64, and the capacitance 66 are connected to one another. In such a state, when the reset transistor 67 is turned on by the driving signal RST, the photodiode 62, the charge-voltage converter 64, and the capacitance 66 are initialized.

Then, when the driving signal RST, the driving signal FDG, and the driving signal TRG are set to the low levels thereafter by the pixel driving circuit 22, the reset transistor 67, the transistor 65, and the transfer transistor 63 are turned off and initialization is canceled. When the initialization is canceled in this manner, the exposure period of the linear pixel 51, that is, the photodiode 62 is started.

When the exposure of the photodiode 62 is started, the photodiode 62 photoelectrically converts the incident light from the subject and accumulates the charge obtained as a result.

When the exposure of the photodiode 62 is continued and the pixel row including the linear pixel 51 is selected as the read line, the pixel driving circuit 22 puts the driving signal SEL, the driving signal RST, and the driving signal FDG supplied to the linear pixel 51 through the driving signal line 25 to the high levels at time t12.

When the driving signal SEL reaches the high level, the selection transistor 74 is turned on and the linear pixel 51 is selected. That is, a signal is output from the linear pixel 51 to the linear pixel readout circuit 24 through the vertical signal line 27.

Furthermore, when the driving signal FDG and the driving signal RST reaches the high levels, the transistor 65 and the reset transistor 67 are turned on, and the charge-voltage converter 64 and the capacitance 66 are initialized in a state where the charge-voltage converter 64 and the capacitance 66 are connected. At that time, since the driving signal TRG remains at the low level, the photodiode 62 remains disconnected from the charge-voltage converter 64, and the exposure of the photodiode 62 is continued.

Then, at time t13, the pixel driving circuit 22 sets the driving signal RST supplied to the linear pixel 51 through the driving signal line 25 to the low level, and finishing the initialization of the charge-voltage converter 64 and the capacitance 66.

Herein, it is possible to switch whether to turn on or off the transistor 65 by appropriately selecting whether to put the driving signal FDG to the high level or the low level.

At that time, the voltage signal according to the accumulated charge of the charge-voltage converter 64 or the accumulated charge in the state where the charge-voltage converter 64 is connected to the capacitance 66 is read out by the linear pixel readout circuit 24 through the amplification transistor 73, the selection transistor 74, and the vertical signal line 27 to be made the reset level of the linear pixel 51. That is, the linear pixel readout circuit 24 reads out the reset level from the linear pixel 51.

Thereafter, the pixel driving circuit 22 sets the driving signal TRG to be supplied to the linear pixel 51 through the driving signal line 25 to the high level at time t14. As a result, the transfer transistor 63 is turned on, the photodiode 62 is connected to the charge-voltage converter 64, and the charge accumulated in the photodiode 62 by the exposure is transferred to the charge-voltage converter 64.

At that time, when the transistor 65 is turned on, a dynamic range of the signal may be expanded in a state where the charge-voltage converter 64 is connected to the capacitance 66. Furthermore, when the transistor 65 is turned off, the charge-voltage converter 64 is disconnected from the capacitance 66, and conversion efficiency of the charge to the voltage signal may be improved.

When the charge transfer from the photodiode 62 to the charge-voltage converter 64 is started in this manner, the exposure period of the photodiode 62 ends.

Furthermore, the pixel driving circuit 22 sets the driving signal TRG supplied to the linear pixel 51 through the driving signal line 25 to the low level and puts the photodiode 62 and the charge-voltage converter 64 into a separated state at time t15.

At that time, the voltage signal corresponding to the accumulated charge in the charge-voltage converter 64 is read out by the linear pixel readout circuit 24 through the amplification transistor 73, the selection transistor 74, and the vertical signal line 27 to be made the signal level of the linear pixel 51. That is, the signal level is read out from the linear pixel 51 by the linear pixel readout circuit 24.

When the reset level and the signal level are read out in this manner, the linear pixel readout circuit 24 generates the pixel signal of the linear pixel 51 by calculation from the reset level and the signal level and outputs the pixel signal to the block at the subsequent stage.

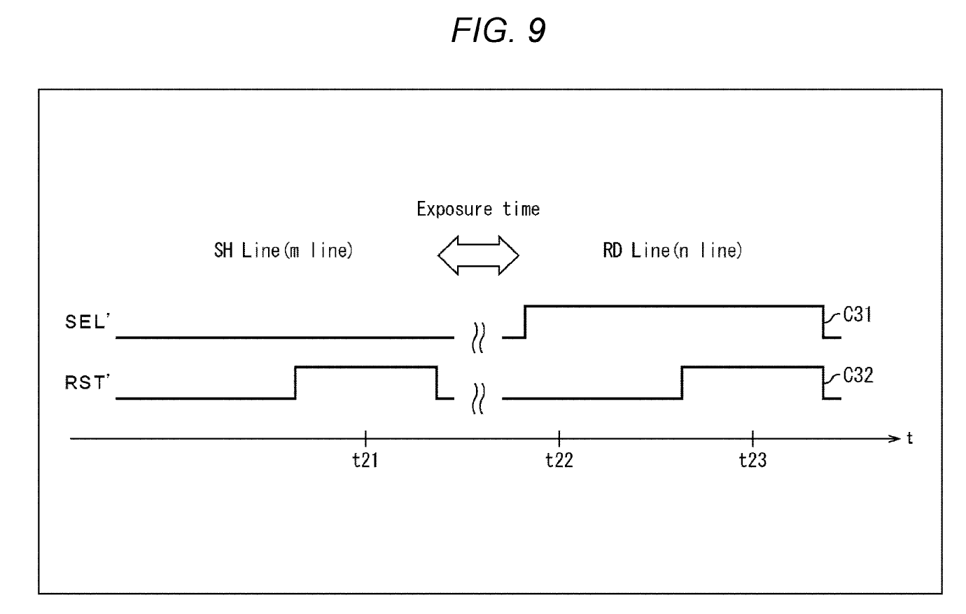

On the other hand, by drive control by the pixel driving circuit 22, the log pixel 101 provided in the pixel array region 21 is driven as illustrated in FIG. 9, for example.

Meanwhile, in FIG. 9, polygonal lines C31 and C32 represent driving waveforms of the above-described driving signals SEL′ and RST′, respectively. Furthermore, in FIG. 9, time is plotted in a lateral direction and the level of each driving signal is plotted in a longitudinal direction. That is, a state in which the driving signal projects upward indicates a high level state, and a state in which the driving signal projects downward indicates a low level state.

In this example, in a case where the pixel row including the log pixel 101 is not selected as either the shutter line or the read line, the driving signals SEL′ and RST′ are set to the low levels. That is, the selection transistor 128 and the reset transistor 124 are turned off.

In such a state, when the pixel row including the log pixel 101 is selected as the shutter line, at time t21, the pixel driving circuit 22 sets the driving signal RST′ supplied to the log pixel 101 through the driving signal line 25 to the high level.

As a result, the reset transistor 124 is turned on and the photodiode 111 is initialized. Then, thereafter, when the driving signal RST′ is set to the low level and the initialization of the photodiode 111 is canceled, the exposure of the photodiode 111 is started. That is, when the initialization of the photodiode 111 is canceled, the exposure period is started.

At the time of the exposure of the photodiode 111, the photodiode 111 photoelectrically converts the incident light, and as a result, the voltage corresponding to the amount of received incident light is applied to the gate electrode of the modulation transistor 112.

When the exposure of the photodiode 111 is continued and the pixel row including the log pixel 101 is selected as the read line, the pixel driving circuit 22 sets the driving signal SEL′ supplied to the log pixel 101 through the driving signal line 25 to a high level at time t22.

When the driving signal SEL′ is set to the high level, the selection transistor 128 is turned on, and the log pixel 101 is selected. That is, the signal is output from the log pixel 101 to the log pixel readout circuit 23 through the vertical signal line 26.

In this case, the voltage (voltage signal) obtained by the photoelectric conversion by the photodiode 111 is read out by the log pixel readout circuit 23 through the modulation transistor 112, the amplification transistor 127, the selection transistor 128, and the vertical signal line 26 and is made the signal level of the log pixel 101. That is, the signal level is read out from the log pixel 101 by the log pixel readout circuit 23.

At the same time as the readout of the signal level, at time t23, the pixel driving circuit 22 sets the driving signal RST′ to be supplied to the log pixel 101 through the driving signal line 25 to the high level.

As a result, the reset transistor 124 is turned on and the photodiode 111 is initialized. When the photodiode 111 is thus initialized, the exposure period of the photodiode 111 ends.

Furthermore, when the photodiode 111 is initialized, the output voltage of the photodiode 111 in that state, that is, the voltage applied to the gate electrode of the modulation transistor 112 is read out by the log pixel readout circuit 23 through the modulation transistor 112, the amplification transistor 127, the selection transistor 128, and the vertical signal line 26 to be made the reset level of the log pixel 101. That is, the log pixel readout circuit 23 reads out the reset level from the log pixel 101.

When the reset level and the signal level are read out in this manner, the log pixel readout circuit 23 generates the pixel signal of the log pixel 101 by calculation from the reset level and the signal level and outputs the pixel signal to the block at the subsequent stage.

When the pixel signals of all the linear pixels 51 and the pixel signals of all the log pixels 101 in the pixel array region 21 are obtained by the above-described driving, the linear image and the log image are obtained.

From the linear image and the log image thus obtained, the final one image is generated by a signal processing block not illustrated of the solid-state imaging device 11 or the signal processing block outside the solid-state imaging device 11, and is made an image of one frame of a still image or a moving image.

The solid-state imaging device 11 repeatedly performs the above-described driving until this is instructed to stop the photographing processing by operation of a user or the like. Then, when the solid-state imaging device 11 is instructed to stop the photographing processing, this stops operation of each part and finishes the photographing process.

In the solid-state imaging device 11, by taking the linear image and the log image as described above, a high-quality image may be obtained more easily.

### Configuration Example of Imaging Device

Furthermore, the present technology is applicable to general electronic apparatuses using a solid-state imaging device in a photoelectric converting unit such as an imaging device such as a digital still camera and a video camera, a mobile terminal device having an imaging function, a copying machine using a solid-state imaging device in an image reading unit.

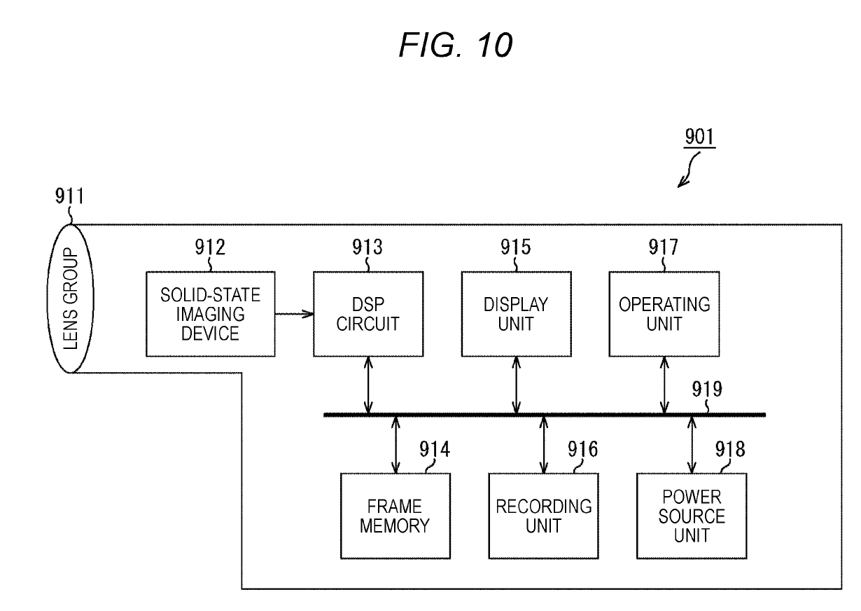

FIG. 10 is a view illustrating a configuration example of the imaging device as the electronic apparatus to which the present technology is applied.

An imaging device 901 in FIG. 10 is provided with an optical unit 911 formed of a lens group and the like, a solid-state imaging device (imaging device) 912, and a digital signal processor (DSP) circuit 913 being a camera signal processing circuit. Furthermore, the imaging device 901 is also provided with a frame memory 914, a display unit 915, a recording unit 916, an operating unit 917, and a power source unit 918. The DSP circuit 913, the frame memory 914, the display unit 915, the recording unit 916, the operating unit 917, and the power source unit 918 are connected to one another through a bus line 919.

The optical unit 911 captures incident light (image light) from a subject to form an image on an imaging surface of the solid-state imaging device 912. The solid-state imaging device 912 converts a light amount of the incident light the image of which is formed on the imaging surface thereof by the optical unit 911 to an electric signal in a pixel unit to output as a pixel signal. The solid-state imaging device 912 corresponds to the solid-state imaging device 11 illustrated in FIG. 5.

The display unit 915 formed of a panel display device such as a liquid crystal panel and an organic electro luminescence (EL) panel, for example, displays a moving image or a still image taken by the solid-state imaging device 912. The recording unit 916 records the moving image or the still image taken by the solid-state imaging device 912 on a recording medium such as a video tape and a digital versatile disk (DVD).

The operating unit 917 issues an operation command regarding various functions of the imaging device 901 under operation by a user. The power source unit 918 appropriately supplies various power sources serving as operation power sources of the DSP circuit 913, the frame memory 914, the display unit 915, the recording unit 916, and the operating unit 917 to supply targets.

Meanwhile, in the above-described embodiment, a case where the present technology is applied to the solid-state imaging device formed of the accumulation type CMOS image sensor in which the pixels detecting the signals corresponding to the light amount of visible light are arranged in a matrix and the logarithmic sensor in the solar cell mode as an example. However, the present technology is not only applied to such the solid-state imaging device, but is applicable also to the solid-state imaging device in general.

### Usage Example of Solid-State Imaging Device

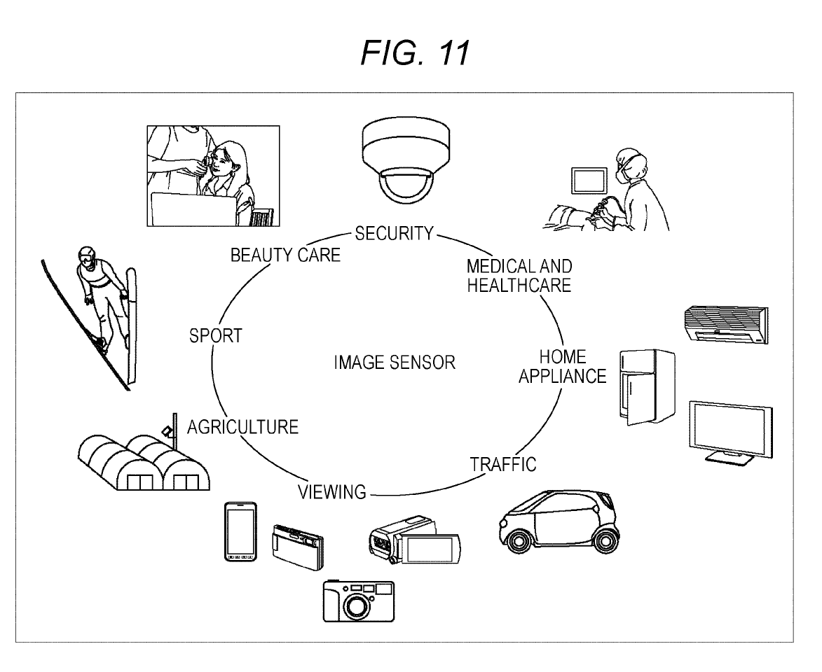

FIG. 11 is a view illustrating a usage example of using the above-described solid-state imaging device (image sensor).

The above-described solid-state imaging device may be used in various cases in which light such as visible light, infrared light, ultraviolet light, and X-ray is sensed as described below, for example.

A device which takes an image to be used for viewing such as a digital camera and a portable device with a camera function

A device for traffic purpose such as an in-vehicle sensor which takes images of the front, rear, surroundings, interior and the like of an automobile, a surveillance camera for monitoring traveling vehicles and roads, and a ranging sensor which measures a distance between vehicles and the like for safe driving such as automatic stop and recognition of a driver's condition and the like

A device for home appliance such as a television, a refrigerator, and an air conditioner which takes an image of a user gesture and performs device operation according to the gesture

A device for medical and healthcare use such as an endoscope and a device which performs angiography by receiving infrared light

A device for security use such as a security monitoring camera and an individual certification camera

A device for beauty care such as a skin condition measuring device which takes an image of skin and a microscope which takes an image of scalp

A device for sporting use such as an action camera and a wearable camera for sporting use and the like

A device for agricultural use such as a camera for monitoring land and crop states

Furthermore, the embodiment of the present technology is not limited to the above-described embodiment and various modifications may be made without departing from the scope of the present technology.

Furthermore, the present technology may have a following configuration.

[1]

A solid-state imaging device including:

a first pixel group formed of a plurality of first pixels arranged in a matrix; and

a second pixel group formed of a plurality of second pixels having a characteristic different from a characteristic of the first pixels arranged in a matrix such that each of the second pixels is displaced by half a pixel in a row direction and in a column direction from each of the first pixels forming the first pixel group.

[2]

The solid-state imaging device according to [1],

in which the first pixel and the second pixel have different output characteristics with respect to an amount of incident light.

[3]

The solid-state imaging device according to [2],

in which the first pixel is a pixel having a linear characteristic as the characteristic.

[4]

The solid-state imaging device according to [2] or [3],

in which the second pixel is a pixel having a log characteristic as the characteristic.

[5]

The solid-state imaging device according to any one of [1] to [4],

in which the first pixel is a pixel forming an accumulation type CMOS image sensor, and the second pixel is a pixel forming a logarithmic sensor in a solar cell mode.

[6]

The solid-state imaging device according to any one of [1] to [5],

in which a pixel row formed of the first pixels arranged in the row direction and a pixel row formed of the second pixels arranged in the row direction adjacent to the pixel row in the column direction are simultaneously selected and driven.

[7]

The solid-state imaging device according to any one of [1] to [6], further including:

a first vertical signal line for reading out signals from the first pixels to which only the first pixels arranged in the column direction are connected; and

a second vertical signal line for reading out signals from the second pixels to which only the second pixels arranged in the column direction are connected.

[8]

The solid-state imaging device according to any one of [1] to [7],

in which the solid-state imaging device is a solid-state imaging device which takes a color image.

[9]

A driving method of a solid-state imaging device provided with:

a first pixel group formed of a plurality of first pixels arranged in a matrix; and

a second pixel group formed of a plurality of second pixels having a characteristic different from a characteristic of the first pixels arranged in a matrix such that each of the second pixels is displaced by half a pixel in a row direction and in a column direction from each of the first pixels forming the first pixel group,

the driving method including steps of:

reading out signals from the first pixels; and

reading out signals from the second pixels.

[10]

An electronic apparatus including:

a solid-state imaging device provided with:

a first pixel group formed of a plurality of first pixels arranged in a matrix; and

a second pixel group formed of a plurality of second pixels having a characteristic different from a characteristic of the first pixels arranged in a matrix such that each of the second pixels is displaced by half a pixel in a row direction and in a column direction from each of the first pixels forming the first pixel group.

### REFERENCE SIGNS LIST

11 Solid-state imaging device

21 Pixel array region

22 Pixel driving circuit

23 Log pixel readout circuit

24 Linear pixel readout circuit

25-1 to 25-6, 25 Driving signal line

26-1 to 26-6, 26 Vertical signal line

27-1 to 27-6, 27 Vertical signal line

51 Linear pixel

101 Log pixel

1. A solid-state imaging device comprising:
a first pixel group formed of a plurality of first pixels arranged in a matrix; and
a second pixel group formed of a plurality of second pixels having a characteristic different from a characteristic of the first pixels arranged in a matrix such that each of the second pixels is displaced by half a pixel in a row direction and in a column direction from each of the first pixels forming the first pixel group.

2. The solid-state imaging device according to claim 1,
wherein the first pixel and the second pixel have different output characteristics with respect to an amount of incident light.

3. The solid-state imaging device according to claim 2,
wherein the first pixel is a pixel having a linear characteristic as the characteristic.

4. The solid-state imaging device according to claim 2,
wherein the second pixel is a pixel having a log characteristic as the characteristic.

5. The solid-state imaging device according to claim 1,
wherein the first pixel is a pixel forming an accumulation type CMOS image sensor, and the second pixel is a pixel forming a logarithmic sensor in a solar cell mode.

6. The solid-state imaging device according to claim 1,
wherein a pixel row formed of the first pixels arranged in the row direction and a pixel row formed of the second pixels arranged in the row direction adjacent to the pixel row in the column direction are simultaneously selected and driven.

7. The solid-state imaging device according to claim 1, further comprising:
a first vertical signal line for reading out signals from the first pixels to which only the first pixels arranged in the column direction are connected; and
a second vertical signal line for reading out signals from the second pixels to which only the second pixels arranged in the column direction are connected.

8. The solid-state imaging device according to claim 1,
wherein the solid-state imaging device is a solid-state imaging device which takes a color image.

9. A driving method of a solid-state imaging device provided with:
a first pixel group formed of a plurality of first pixels arranged in a matrix; and
a second pixel group formed of a plurality of second pixels having a characteristic different from a characteristic of the first pixels arranged in a matrix such that each of the second pixels is displaced by half a pixel in a row direction and in a column direction from each of the first pixels forming the first pixel group,
the driving method comprising steps of:
reading out signals from the first pixels; and
reading out signals from the second pixels.

10. An electronic apparatus comprising:
a solid-state imaging device provided with:
a first pixel group formed of a plurality of first pixels arranged in a matrix; and
a second pixel group formed of a plurality of second pixels having a characteristic different from a characteristic of the first pixels arranged in a matrix such that each of the second pixels is displaced by half a pixel in a row direction and in a column direction from each of the first pixels forming the first pixel group.
